(19) United States
(12) Patent Application Publication
(10) Pub. No.: US 2020/0203083 A1
(43) Pub. Date: Jun. 25, 2020

(54) FABRICATION OF STABLE PEROVSKITE-BASED OPTOELECTRONIC DEVICES

(71) Applicant: OKINAWA INSTITUTE OF SCIENCE AND TECHNOLOGY SCHOOL CORPORATION, Kunigami-Gun (JP)

(72) Inventors: Yabing Qi, Kunigami-gun (JP); Sonia Ruiz Raga, Kunigami-gun (JP); Luis Katsuya Ono, Kunigami-gun (JP)

(73) Assignee: OKINAWA INSTITUTE OF SCIENCE AND TECHNOLOGY SCHOOL CORPORATION, Kunigami-Gun (JP)

(21) Appl. No.: 16/674,126

(22) Filed: Nov. 5, 2019

Related U.S. Application Data
(63) Continuation of application No. 15/567,282, filed on Oct. 17, 2017, now abandoned.
(60) Provisional application No. 62/165,575, filed on May 22, 2015.

(51) Int. Cl. H01G 9/20; H01L 51/42; H01L 51/00; H01G 9/00

(52) U.S. Cl. CPC H01G 9/2009; Y02E 10/549; H01L 51/0007; H01G 9/0036; H01L 51/0032; H01L 51/4226; H01L 51/0094; H01L 51/0078; H01L 51/0077; H01L 51/0072; H01L 51/006; H01L 51/0059; H01L 51/0058; H01L 51/0056; H01L 51/0055; H01L 51/0037; H01L 51/0036; H01L 51/0035; H01L 51/424

(57) ABSTRACT

A method of fabricating a perovskite-based optoelectronic device is provided, the method comprising: forming an active layer comprising organometal halide perovskite; making a solution comprising a hole transport material (HTM) and a solvent, the solvent having a boiling point lower than that of chlorobenzene; and forming a hole transport layer (HTL) by spin-coating the solution on the active layer. The solvents having a boiling point lower than that of chlorobenzene include chloroform and dichloromethane.

### CROSS REFERENCE TO RELATED APPLICATIONS

This is a Continuation of U.S. application Ser. No. 15/567,282 filed Oct. 17, 2017, which is a 371 of PCT/JP2016/002250 filed May 6, 2016, which claims benefit of 62/165,575 filed May 22, 2015, the entire contents of which is incorporated herein by reference.

### TECHNICAL FIELD

The present invention relates to stable perovskite-based optoelectronic devices and a fabrication method thereof.

### BACKGROUND ART

A solar cell (also called a photovoltaic cell) is an electrical device that converts solar energy into electricity by using semiconductors that exhibit the photovoltaic effect. Solar photovoltaics is now, after hydro and wind power, the third most important renewable energy source in terms of globally installed capacity. Constructions of these solar cells are based around the concept of a p-n junction, wherein photons from the solar radiation are converted into electron-hole pairs. Examples of semiconductors used for commercial solar cells include monocrystalline silicon, polycrystalline silicon, amorphous silicon, cadmium telluride, and copper indium gallium diselenide. Solar cell energy conversion efficiencies for commercially available cells are currently reported to be around 14-22%.

High conversion efficiency, long-term stability and low-cost fabrication are essential for commercialization of solar cells. For this reason, a wide variety of materials have been researched for the purpose of replacing conventional semiconductors in solar cells. For example, the solar cell technology using organic semiconductors is relatively new, wherein these cells may be processed from liquid solution, potentially leading to inexpensive, large scale production. Besides organic materials, organometal halide perovskites, CH₃NH₃PbX₃ and CH₃NH₃SnX₃, where X=Cl, Br, I or a combination thereof, for example, have recently emerged as a promising material for the next generation of high efficiency, low cost solar technology. It has been reported that these synthetic perovskites can exhibit high charge carrier mobility and lifetime that allow light-generated electrons and holes to move far enough to be extracted as current, instead of losing their energy as heat within the cell. These synthetic perovskites can be fabricated by using the same thin-film manufacturing techniques as those used for organic solar cells, such as solution processing, vacuum evaporation techniques, chemical vapor deposition, etc.

Recent reports have indicated that this class of materials, i.e., organometal halide perovskites, have potential for high-performance semiconducting media in other optoelectronic devices as well. In particular, some perovskites are known to exhibit strong photoluminescence properties, making them attractive candidates for use in light-emitting diodes (LEDs). Additionally, it has been reported that perovskites also exhibit coherent light emission properties, hence optical amplification properties, suitable for use in electrically driven lasers. In these devices, electron and hole carriers are injected into the photoluminescence media, whereas carrier extraction is needed in solar cell devices.

However, to date, it has been difficult to obtain stable perovskite-based devices using existing fabrication techniques. In view of ever increasing needs for low cost fabrication techniques of high-performance devices, a new fabrication technique is desired for producing stable and highly efficient perovskite-based devices suitable for solar cells and other optoelectronics applications.

### CITATION LIST

### Non Patent Literature

NPL1: G. E. Eperon et al., Formamidinium lead trihalide: a broadly tunable perovskite for efficient planar heterojunction solar cells. Energy Environ. Sci. 7, 982-988 (2014).
NPL2: Z. Hawash et al., Air-exposure induced dopant redistribution and energy level shifts in spin-coated spiro-MeOTAD films. Chem. Mater. 27, 562-569 (2015).
NPL3: J. Burschka et al., Sequential deposition as a route to high-performance perovskite-sensitized solar cells. Nature Vol. 499, 316-320 (July, 2013).

### Patent Literature

PL1: Lupo et al., U.S. Pat. No. 5,885,368
PL2: Windhap et al., U.S. Pat. No. 6,664,071
PL3: Onaka et al., U.S. Pat. No. 8,642,720

### PL4: Isobe et al., US 2012/0085411A1

### PL5: Nishimura et al., US 2012/0325319A1

### PL6: Kawasaki et al., US 2013/0125987A1

### PL7: Horiuchi et al., US 2014/0212705A

### PL8: Arai et al., US 2015/0083210A

### PL9: Arai et al., US 2015/0083226A1

### PL10: Snaith et al., US 2015/0122314A1

### SUMMARY

A method of fabricating a perovskite-based optoelectronic device is provided, the method comprising: forming an active layer comprising organometal halide perovskite; making a solution comprising a hole transport material (HTM) and a solvent, the solvent having a boiling point lower than that of chlorobenzene; and forming a hole transport layer (HTL) by spin-coating the solution on the active layer. The solvents having a boiling point lower than that of chlorobenzene include chloroform and dichloromethane.

### BRIEF DESCRIPTION OF DRAWINGS

FIG. 1 shows photos of the AFM image of the chlorobenzene (ClB) cell in (a), the AFM image of the chloroform (ClF) cell in (b), the SEM image of the ClB cell in (c), and the SEM image of the ClF cell in (d).

FIG. 2 shows plots of the j-V curves of the ClB cells in (a) and the ClF cells in (b).

FIG. 3 shows plots of power conversion efficiency (PCE), open-circuit voltage (V_{oc}), short-circuit current (j_{sc}), fill factor (FF) values measured in air over ˜102 hours, of 5 individual ClB cells based on the forward scan in (a) and the reverse scan in (b).

FIG. 4 shows plots of PCE, j_{sc}, V_{oc}, and FF values measured in air over ˜102 hours, of 6 individual ClF cells based on the forward scan in (a) and the reverse scan in (b).

FIG. 5 shows plots of post-mortem XPS corresponding to the I 3d core level of the ClB and ClF cells measured after 102 hours of the stability test.

FIG. 6 shows the AFM image of the spin-coated spiro-MeOTAD film prepared with dichloromethane (CH₂Cl₂).

FIG. 7 shows the AFM images of spin-coated polystyrene films prepared by using chloroform in (a) and chlorobenzene in (b).

### DESCRIPTION OF EMBODIMENTS

Source materials in conventional methods for fabricating an organometal halide perovskite film include halide materials such as PbCl₂, PbBr₂, PbI₂, SnCl₂, SnBr₂, SnI₂ and the like, and methylammonium (MA=CH₃NH₃⁺) compounds such as CH₃NH₃Cl, CH₃NH₃Br, CH₃NH₃I, and the like. In place of, or in a combination with the MA compound, a formamidinium (FA=HC(NH₂)₂⁺) compound can also be used. Organometal halide perovskites have the orthorhombic structure generally expressed as ABX₃, in which an organic element, MA, FA or other suitable organic element, occupies each site A; a metal element, Pb²⁺or Sn²⁺, occupies each site B; and a halogen element, Cl⁻, I⁻or Br⁻, occupies each site X. (See, for example, Eperon et al., NPL1.) Source materials are denoted as AX and BX₂, where AX represents an organic halide compound having an organic element MA, FA or other suitable organic element for the A-cation combined with a halogen element Cl, I or Br for the X-anion; BX₂ represents a metal halide compound having a metal element Pb or Sn for the B-cation combined with a halogen element Cl, I or Br for the X-anion. Here, the actual element X in the AX and the actual element X in the BX₂ can be the same or different, as long as each is selected from the halogen group. For example, X in the AX can be Cl, while X in the BX₂ can be Cl, I or Br. Accordingly, formation of a mixed perovskite, e.g., MAPbI₃₋ₓClₓ, is possible. The terms “perovskite” and “organometal halide perovskite” are used interchangeably and synonymously in this document.

Organometal halide perovskite can be used for an active layer in an optoelectronic device, such as a solar cell, LED, laser, etc. Here, the “active layer” refers to an absorption layer where the conversion of photons to charge carriers (electrons and holes) occurs in a photovoltaic device; for a photo-luminescent device, it refers to a layer where charge carriers are combined to generate photons. A hole transport layer (HTL) can be used as a medium for transporting hole carriers from the active layer to an electrode in a photovoltaic device; for a photo-luminescent device, the HTL refers to a medium for transporting hole carriers from an electrode to the active layer. Examples of hole transport materials (HTMs) for use for forming HTLs in perovskite-based devices include but not limited to: 2,2′,7,7′-tetrakis(N,N′-di-p-methoxyphenylamine) -9,9′-spirobifluorene (spiro-MeOTAD, also called spiro-OMeTAD), polystyrene, poly(3-hexylthiophene-2,5-diyl) (P3HT), poly(triarylamine) (PTAA), graphene oxide, nickle oxide, poly(3,4-ethylenedioxythiophene) polystyrene sulfonate (PEDOT:PSS), copper thiocyanate (CuSCN), CuI, Cs₂SnI₆, alpha-NPD, Cu₂O, CuO, subphthalocyanine, 6,13-bis(triisopropylsilylethynyl) pentacene (TIPS-pentacene), PCPDTBT, PCDTBT, OMeTPA-FA, OMeTPA-TPA, and quinolizino acridine.

A solution method is typically employed to form an HTL for a perovskite-based device. For example, the solution of spiro-MeOTAD with 4-tert-butylpiridine (tBP) and lithium bis-(trifluoromethylsulfonyl)imide salt (Li-salt) may be spin-coated to form the HTL on a perovskite film. However, a recent study described in Hawash et al. (NPL2) revealed that these solution-processed films made of spiro-MeOTAD typically include pinholes with a high density. Here, a pinhole is defined as a defect having a shape of a hole with a small diameter penetrating in the film. These pinholes may penetrate through the entire thickness of the film or deeply into the film starting from the film surface. These pinholes in the HTL can cause instability of perovskite-based devices, via shortening or mixing between layers, which is likely the reason why a typical perovskite solar cell using a solution-processed spiro-MeOTAD film for forming the HTL shows rapidly reduced efficiency when exposed to air. These pinholes are also likely the cause for the very short lifetime of typical perovskite solar cells, which include solution-processed spiro-MeOTAD for the HTL. The effects are considered to be twofold: (i) pinholes facilitate moisture migration through the HTL to reach and degrade the perovskite; (ii) pinholes facilitate component elements, e.g., iodine, from the perovskite to migrate to the top surface and degrade or decompose the perovskite. Based on such observations, it is noted that the choice of solvents for the preparation of spiro-MeOTAD for use as the HTL be optimized to avoid pinhole formation, thereby to increase the lifetime of perovskite solar cells.

This document includes descriptions of experiments and analyses that were conducted to clarify the role of solvents in preparing a hole transport material (HTM) to be deposited on a perovskite film, with the aim to reduce the number of pinholes in the resultant HTL. In the following, spiro-MeOTAD is used as a specific HTM example; however, the present methodology is applicable to other types of HTMs. First, the case of using chloroform as a solvent is considered, instead of commonly used chlorobenzene. Details are described below with reference to accompanying drawings. Although specific values are cited herein to explain various steps, experiments and analyses as examples, it should be understood that these are approximate values and/or within measurement tolerances.

Transparent conductive substrates were prepared by using fluorine-doped tin oxide coated on glass (FTO) in an example process. The FTO was etched and cleaned by brushing with an aqueous solution of sodium dodecyl sulfate, rinsing with water, followed by sonication in 2-propanol, and finally drying with N₂ gas. An 80 nm-thick TiO₂ compact layer was deposited by spray-pyrolisis using a 3:3:1 wt. mixture of acetylacetone, Ti (IV) isopropoxyde and anhydrous ethanol. Mesostructured TiO₂ layers of ˜170 nm thicknesses were deposited by spin-coating a diluted paste (90-T) in terpineol 1:3 wt. at 4000 rpm and subsequently sintered at 350° C. for 10 min and 480° C. for 30 min After cooling down, the substrates were treated in UV-O₃ for 15 min and transferred in a N₂ glovebox for perovskite deposition.

Next, perovskite deposition on the substrate was performed by following a modified two-step solution method, as described in Burschka et al. (NPL3). First, a solution of PbI₂ in dimethylformamide (460 mg mL⁻¹) was prepared and left stirring at 70° C. for at least 2 hours. The solution was spin-coated on the mesostructured TiO₂ substrates, previously heated at 70° C., at 6000 rpm for 30 seconds. Before starting the spin-coating, the solution was left for 10 seconds on the mesoporous layer for proper pore infiltration. After the spin-coating, PbI₂ layer was dried at 70° C. for 20 min For the second step, a 20 mg mL⁻¹ methylammonium iodide (MAI) solution in 2-propanol (IPA) was prepared and kept at 70° C. The PbI₂ films were dipped in the MAI solution during 30 seconds with gentle shaking of the substrate. After dipping, the substrates were rinsed in abundant IPA and dried immediately by spinning the sample using the spin-coater and annealed for 20 min on the hot plate at 70° C. The resultant perovskite is MAPbI₃ in this case.

Next, solar cells were fabricated by using the perovskite films deposited on the respective substrates. A first batch of solar cell samples was fabricated, each including a HTL prepared by using a mixture of three materials: spiro-MeOTAD dissolved in chlorobenzene with 72.5 mg/mL concentration, 17.5 μL of Li-bis(trifluoromethanesulfonyl)-imide (LiTFSI) dissolved in acetronitrile (52 mg/100 μL), and 28.8 μL of tert-butylpyridine (t-BP). This mixture solution was spin-coated on the perovskite films, giving rises to the first batch of solar cell samples, termed ClB cells herein. A second batch of solar cell samples was fabricated, each including a HTL prepared by using chloroform as a solvent, instead of chlorobenzene, keeping all the other materials the same. The mixture solution including chloroform, instead of chlorobenzene, was spin-coated on the perovskite films. These cells are termed ClF cells herein. Finally, for both batches, Au top electrodes (100 nm) were deposited by thermal evaporation through a shadow mask defining solar cell active areas of 0.05, 0.08, 0.12, and 0.16 cm².

Perovskite film characterizations by scanning electron microscopy (SEM), X-ray diffraction (XRD), and UV-visible spectroscopy were performed. The characteristic XRD peaks at 14.1°, 28.4° and 43.2° were observed in the as-prepared perovskite films, corresponding to the (110), (220) and (330) planes in the orthorhombic crystal structure. SEM images indicated a uniform layer completely covering the mesostructured TiO₂ film, with perovskite crystal domains in the range of 50-100 nm. The onset in absorbance of the perovskite film in the UV-visible scan confirmed an optical band gap of 1.58 eV.

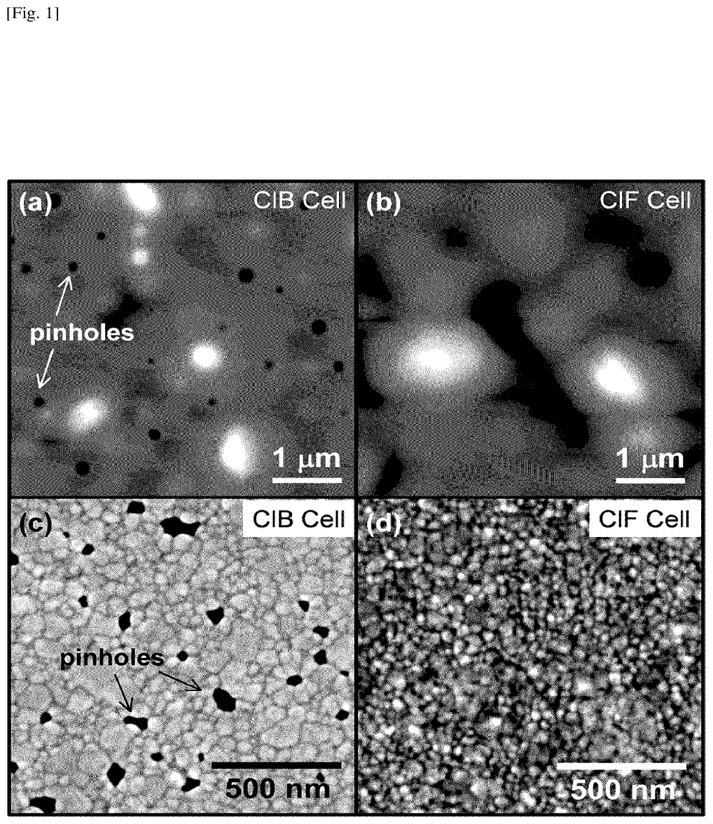

Morphology characterizations of the HTLs were carried out based on atomic force microscopy (AFM) and SEM. FIG. 1 shows photos of the AFM image of the ClB cell in (a), the AFM image of the ClF cell in (b), the SEM image of the ClB cell in (c), and the SEM image of the ClF cell in (d). The AFM images were acquired on the spiro-MeOTAD regions not covered by the Au electrodes. The SEM images were acquired on the Au electrodes. The presence of pinholes in the spiro-MeOTAD HTL of the ClB cell is evident in (a), whereas pinholes are not visibly present in the HTL of the ClF cell in (b). Voids caused by the pinholes underneath are also observed in the Au electrodes of ClB cells, as shown in (c), reflecting the spiro-MeOTAD film morphology underneath the Au electrode. On the other hand, voids are not visibly present in the Au electrode of the ClF cell in (d).

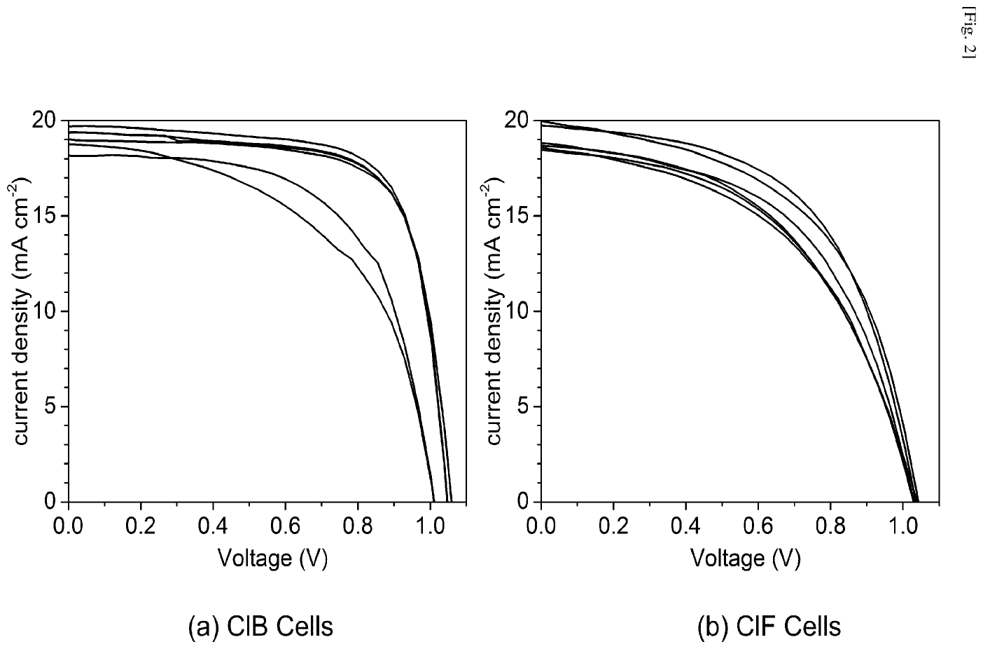

FIG. 2 shows plots of the j-V curves of the ClB cells in (a) and the ClF cells in (b). The specific layer sequence is: FTO/bl-TiO₂/mp-TiO₂/MAPbI₃/spiro-MeOTAD/Au. The cells were irradiated under 1 sun (AM1.5G). The champion cell (i.e., the best performing cell) in the ClB batch exhibited the open-circuit voltage (V_{oc}), short-circuit current (j_{sc}), fill factor (FF), and power conversion efficiency (PCE) of 1.047 V, 19.7 mA/cm², 0.72, and 14.9%, respectively. The champion cell in the ClF batch exhibited V_{oc}, jₛₑ, FF, and PCE of 1.036 V, 19.7 mA/cm², 0.56, and 11.4%, respectively. The lower fill factor and PCE of the ClF cells having the chloroform-prepared HTL are considered to be due to an increase in series resistance, which is attributed to a slower air-induced dopant redistribution of the spiro-MeOTAD layer in the absence of pinholes. The air exposure step after the spin-coating of spiro-MeOTAD layer before the top contact evaporation is considered to be important for achieving optimal efficiencies.

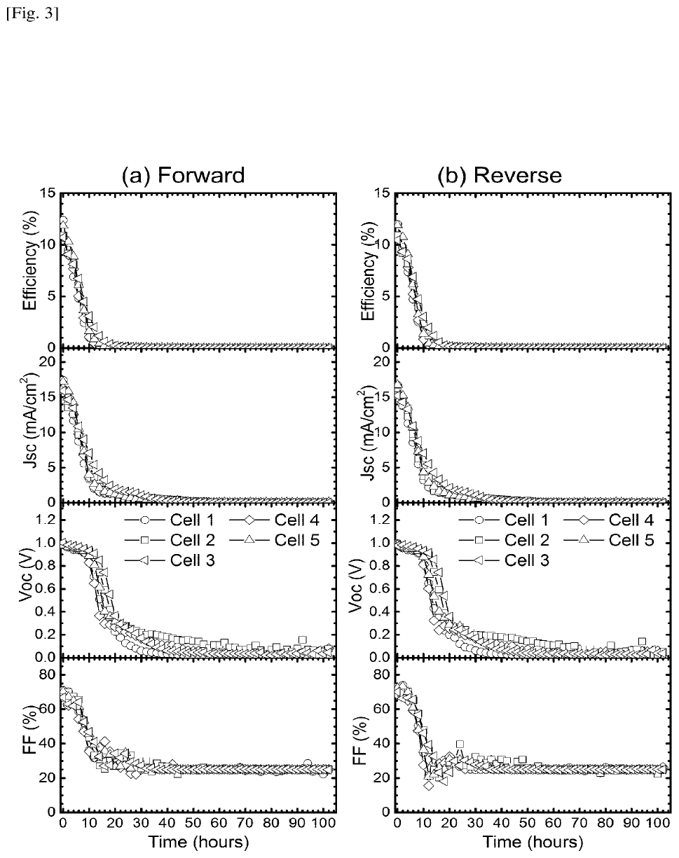

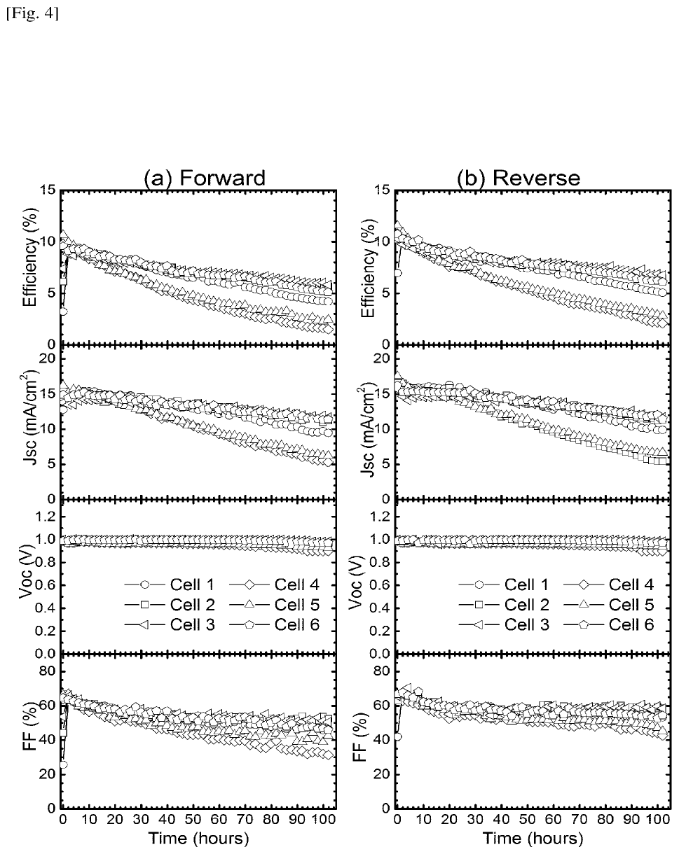

The evolution of steady-state solar cell performance parameters was monitored over ˜102 hours in ambient air. The transient photocurrent signals were measured every two hours. The stability measurement procedure adopted here corresponds to the ISOS-L-1 protocol. It should be noted that one of the common behaviors pertaining to perovskite solar cells is hysteresis. That is, the current density level is not at the same voltage when the voltage is changed from high to low vs. from low to high. To take into account such a hysteresis behavior, both forward and reverse scans were carried out, wherein the forward scan sweeps the voltage from low to high (i.e. the direction from jsc to Voc in a j-V plot), and the reverse scan sweeps the voltage from high to low (i.e. the direction from Voc to jsc in a j-V plot). FIG. 3 shows plots of PCE, jₛₑ, V_{oc}, and FF values measured in air over ˜102 hours, of 5 individual ClB cells based on the forward scan in (a) and the reverse scan in (b). FIG. 4 shows plots of PCE, j_{sc}, V_{oc}, and FF values measured in air over ˜102 hours, of 6 individual ClF cells based on the forward scan in (a) and the reverse scan in (b). The humidity was controlled to be ˜42%. Upon comparing FIGS. 3 and 4, it is seen clearly that each solar cell parameter of the ClB cells degrades sharply immediately after the air exposure until 10-20 hours, followed by a long tail of slow decrease until the end of measurements. All the ClB cells yielded the PCE value of 0% after 12 hours of continuous operation at the maximum power point. On the other hand, the ClF cells show significantly better stability as seen in FIG. 4. Statistical analyses on the ClF cells show that PCE value decreased only by ˜12% from the initial PCE during the first 12 hours. After ˜100 hours of operation, PCE of the C1F cells decreased by ˜50%. The PCE profile is considered to reflect the interplay of j_{sc}, V_{oc}, and FF profiles. Because the perovskite-based solar cell structure is complex (FTO/bl-TiO₂/mp-TiO₂/MAPbI₃/spiro-MeOTAD/Au), convoluted physical-chemical changes in each layer are expected to affect the overall j_{sc}, V_{oc}, and FF profiles. The decay in j_{sc} observed in the ClB cells can be attributed mainly to the degradation of the MAPbI₃ active (i.e., absorption) layer generating decreasing photocurrent as a function of operation time.

XRD results also confirmed that the perovskite crystalline peaks disappear in the ClB cells after ˜100-hour operation. It is considered that the degradation of the perovskite layer is induced by the reaction with H₂O (moisture) in atmosphere generating MA, MAI, PbI₂, and hydriodic acid (HI) as by-products. Furthermore, HI and MA have boiling temperatures of −35.4° C. and −6° C., respectively; thus, they are present mainly in gas phase at room temperature. A slow linear-type decay is observed in the monitored ˜100-hour stability profile of the ClF cells. As described above, AFM images in FIG. 1 (a) and (b) show distinctly different morphology between the ClB and ClF cells. These are the spiro-MeOTAD regions not covered by Au electrodes. A high density of pinholes is observed in the ClB cells and expected to promote the inward diffusion of H₂O and O₂ gas molecules present in the ambient air, thereby degrading the MAPbI₃ active layer, as well as the outward diffusion of by-products having high vapor pressure such as MAI and/or HI.

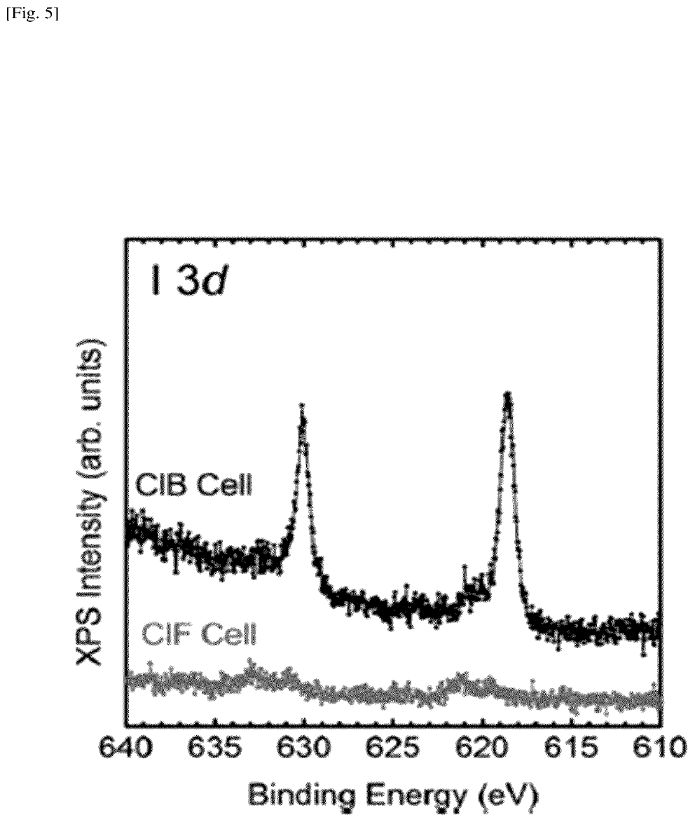

As evident in the AFM images such as those in FIG. 1 (a) and (b), the C1F cells have a very uniform and high coverage surface, which is qualitatively different in comparison with the ClB cells, wherein pinholes can be easily identified. Such observations are also corroborated by XPS measurements. FIG. 5 shows plots of post-mortem XPS corresponding to the I 3d core level of the ClB and ClF cells measured after 102 hours of the afore-mentioned stability test. In general, XPS measurements are surface sensitive and can detect the presence of elements up to approximately 10 nm deep from the top surface. As shown in FIG. 5, for the ClB cell, the XPS peaks associated with the I 3d core level are very strong, which clearly indicates the outward diffusion of by-products with high vapor pressure such as MAI and/or HI to the top-surface of HTL. A large amount of iodine-containing compound (most likely MAI) was detected by the XPS, as shown in FIG. 5, on the top surface of ClB cells. ClF cells also showed that some iodine species were present on the top surface, meaning that the pinhole-free spiro-MeOTAD layer is still not able to completely stop the diffusion.

On the basis of the combined results of AFM, SEM and XPS, it is concluded that each ClF cell has a significantly less number of pinholes in the HTL than the ClB cells. The fundamental aspects and mechanisms for the pinhole formation are complex and may involve multiple factors. Properties of solvents used in the HTL preparation are considered to affect the crystallinity and morphology of the fabricated films. To elucidate the fundamental mechanisms for the pinhole formation, different solvents and HTMs were tested. Some examples are described below.

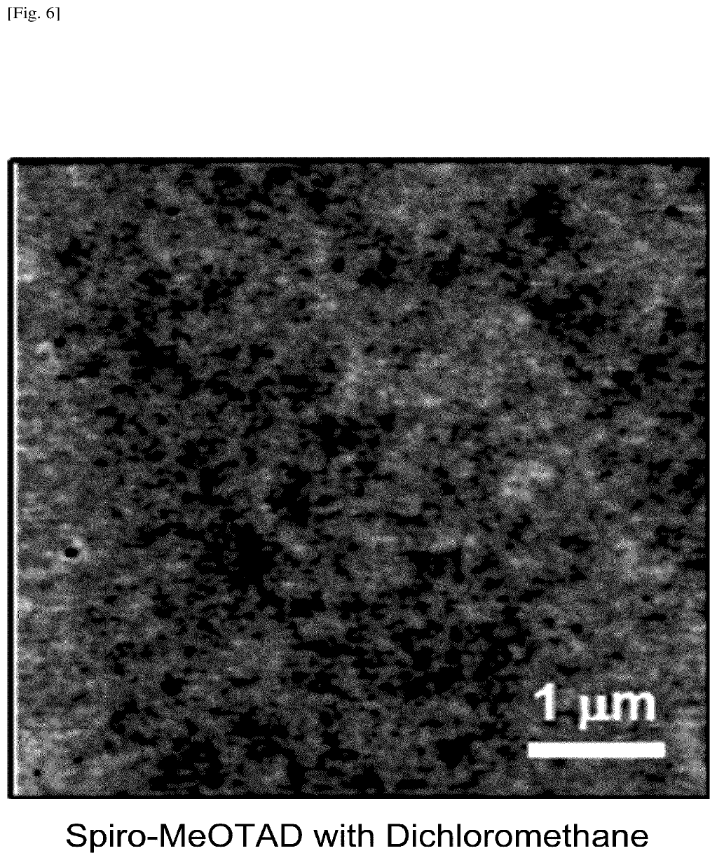

The solution of spiro-MeOTAD and dichloromethane (CH₂Cl₂) as the solvent was prepared, and spin-coated on a Si substrate to form a HTL layer with a thickness of ˜400 nm. FIG. 6 shows the AFM image (5×5 μm²) of the spin-coated spiro-MeOTAD film prepared with CH₂Cl₂. A very low density of pinholes with small diameters was observed. Results of statistical analyses show that the size of pinholes is 107±2 nm in diameter, and the density is 0.5 pinhole/μm², both smaller than those observed in the ClB cells.

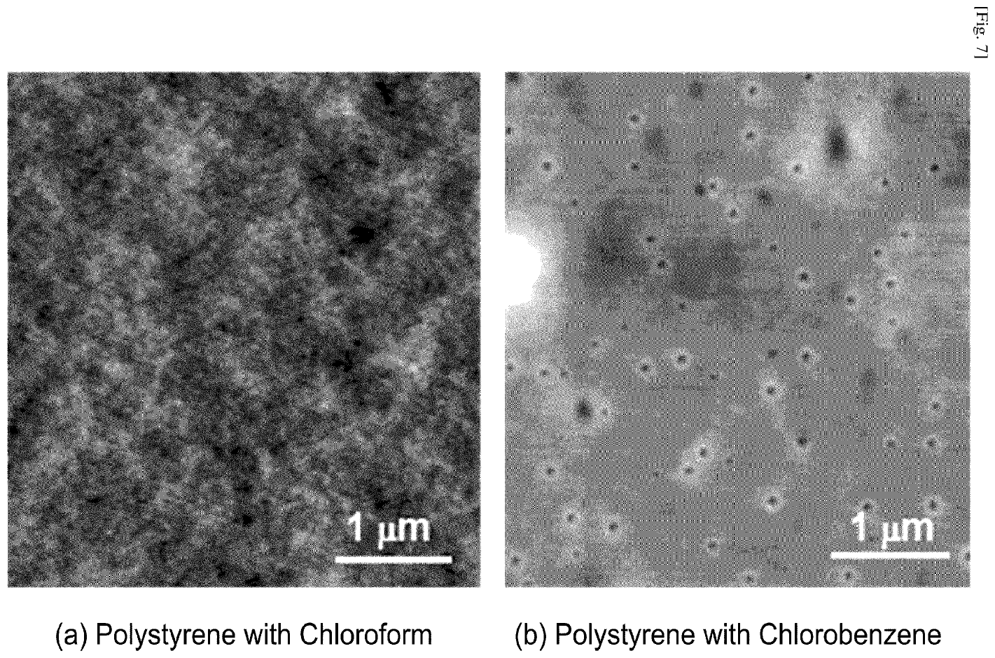

Similar experiments were conducted by using polystyrene for forming the HTL, instead of spiro-MeOTAD. Polystyrene is a polymer, which is different from a small molecule material such as spiro-MeOTAD. FIG. 7 shows the AFM images (4×4 μm²) of spin-coated polystyrene films prepared by using chloroform in (a) and chlorobenzene in (b). Pinholes were observed when the chlorobenzene solvent was employed, as shown in (b). Similar effects on the pinhole formation arising from the choice of solvents can be expected upon using a different type of HTM, such as P3HT, PTAA, graphene oxide, nickle oxide, PEDOT:PSS, CuSCN, CuI, Cs₂SnI₆, alpha-NPD, Cu₂O, CuO, subphthalocyanine, TIPS-pentacene, PCPDTBT, PCDTBT, OMeTPA-FA, OMeTPA-TPA, and quinolizino acridine.

According to the present method for fabricating a HTL that has minimal density and sizes of pinholes, selection of the solvent for dissolving the HTM plays an important role. The crystallinity and morphology of the prepared film may be affected by the physical properties of the solvent, for example, the boiling point, dipole moment, viscosity, solubility, and so on. It should be noted that the boiling point of chlorobenzene (132° C.) is significantly higher than that of chloroform (61.2° C.) and that of dichloromethane)(39.6° . The faster vaporization of a low-boiling point solvent is considered to help solidify the HTL film quickly with minimal generation of pinholes. The present method pertains to formation of a high-quality HTL with reduced pinholes on a perovskite active layer, leading to enhanced stability and long lifetime of the device. Thus, it is applicable to fabricating any perovskite-based optoelectronic devices, including solar cells, LEDs, lasers, and the like.

While this document contains many specifics, these should not be construed as limitations on the scope of an invention or of what may be claimed, but rather as descriptions of features specific to particular embodiments of the invention. Certain features that are described in this document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be exercised from the combination, and the claimed combination may be directed to a subcombination or a variation of a subcombination.

1. A method of fabricating a perovskite-based optoelectronic device, the method comprising:
forming an active layer comprising organometal halide perovskite;
making a solution comprising a hole transport material (HTM) and chloroform as a solvent, the solvent having a boiling point lower than that of chlorobenzene; and
forming a hole transport layer (HTL) by spin-coating the solution on the active layer.

2. The method of claim 1, wherein
the HTM is selected from a group consisting of spiro-MeOTAD, polystyrene, P3HT, PTAA, graphene oxide, nickle oxide, PEDOT:PSS, CuSCN, CuI, Cs₂SnI₆, alpha-NPD, Cu₂O, CuO, subphthalocyanine, TIPS-pentacene, PCPDTBT, PCDTBT, OMeTPA-FA, OMeTPA-TPA, and quinolizino acridin.

3. The method of claim 2, wherein
the organometal halide perovskite is ABX₃ where A is MA or FA, B is Pb or Sn, and X is Cl, I or Br.

4. The method of claim 1, wherein a density of pinholes of the HTL is 0.5 pinhole/μm² or less, and a thickness of the HTL is equal to or more than 400 nm.

5. The method of claim 4, wherein the thickness of the HTL is substantially 400 nm.

6. A method of fabricating a perovskite-based optoelectronic device, the method comprising:
forming an active layer comprising organometal halide perovskite;
making a solution comprising a hole transport material (HTM) and a solvent, the solvent having a boiling point lower than that of chlorobenzene;
selecting the solvent that minimizes pinhole formation in the HTM, the selecting includes observing the amount of pinhole formation after the solvent is added to the HTM; and
forming a hole transport layer (HTL) by spin-coating the solution on the active layer.

7. The method of claim 6, wherein
the observing includes conducting morphology characterizations of the HTL.

8. The method of claim 7, wherein
the observing includes analyzing the combined results of AFM, SEM and XPS measurements of the HTL.
